(19) United States
(12) Patent Application Publication
(10) Pub. No.: US 2004/0101388 A1
(43) Pub. Date: May 27, 2004

(54) Fabrication system having a clean room on two floors, a clean room, a semiconductor wafer delivery system, and method of performing subsequent fabrication processes on a semiconductor wafer

(76) Inventor: Che Young Lee, Suwon-City (KR)

Correspondence Address: HARNESS, DICKEY & PIERCE, P.L.C., P.O. BOX 8910, RESTON, VA, 20195, US

(21) Appl. No.: 10/423,952

(22) Filed: Apr. 28, 2003

(30) Foreign Application Priority Data
Nov. 27, 2002 (KR) 2002-74375

(51) Int. Cl. H01L 21/00

(52) U.S. Cl. 414/416.08

(57) ABSTRACT

A fabrication system for producing semiconductor devices having a clean room on two floors, a method of performing subsequent fabrication processes, a clean room, and a semiconductor wafer deliver system. The fabrication system includes first and second clean rooms on upper and lower floors respectively. Each of the first and second clean rooms includes a plurality of main bays that contain semiconductor fabrication apparatuses for performing semiconductor processes. A plurality of paths are positioned substantially perpendicular to the main bays and divide the main bays into a plurality of sub bays. Semiconductor wafer delivery systems may be located in the sub bays near the paths to transfer semiconductor wafers between the first and second clean rooms.

### CROSS-REFERENCE TO RELATED APPLICATIONS

This U.S. non-provisional application claims priority under 35 U.S.C. §119 to Korean Patent Application No. 2002-74375, filed on Nov. 27, 2002, the contents of which are incorporated by reference in their entirety.

### BACKGROUND OF THE INVENTION

1. Field of the Invention

The present invention relates generally to fabricating semiconductor devices, and more particularly, to a fabrication system for producing semiconductor devices that has a clean room on two floors, a clean room for producing semiconductor devices, a semiconductor wafer delivery system, and a method of performing subsequent fabrication processes on a semiconductor wafer.

2. Description of the Related Art

The working area in a production line for manufacturing semiconductor devices should have a heightened level of cleanliness to reduce the possibility of contaminating the semiconductor wafers. As a result, manufacturing apparatuses that perform processes on semiconductor wafers that need to have a clean working area are separated from apparatuses that perform processes that do not need to have a clean working area. Thus, systems for semiconductor fabrication may include a clean room in which a high level of cleanliness is maintained and a service floor located below the clean room that has a lower level of cleanliness. Two clean rooms may be formed on two floors in a semiconductor fabrication line to obtain a wider clean room in the same area and to increase the production capacity for the semiconductor devices.

FIGS. 1 and 2 are schematic perspective and plan views of a conventional semiconductor fabrication line including a conventional clean room.

The conventional semiconductor fabrication line depicted in FIG. 1 includes a clean room 1113 having a rectangular shape and a service floor 1111 located below the clean room 1113. Concomitant apparatuses used in the semiconductor fabrication process, e.g., a vacuum pump, a scrubber, and an exhausting plumb, which do not need to have a clean working area, are located in the service floor 1111. Semiconductor fabrication devices that need a clean working environment are located in the clean room 1113. The clean room 1113 may be maintained at a heightened level of cleanliness, e.g., a class 1 room.

Referring to FIG. 2, the clean room 1113 may have a generally rectangular shape, e.g., with a long side and a short side. Bays 1133 are positioned in the clean room 1113 along the long side of the clean room 1113. Semiconductor devices 200 are arranged along the sides of the bays 1133. In the center of each bay 1133, a bay path 1137 is formed in a lengthwise direction. A main path 1131 is formed in the center of the clean room 1113 between the bays 1133. Bay entrances 1135 are located at points where the main path 1131 intersects each of the bays 1133. A semiconductor wafer delivery system 1300 is positioned near the bay entrance 1135 at each bay 1133 to deliver a cassette that contains a plurality of semiconductor wafers between the bays 1133. Therefore, after a semiconductor process is completed in one of the bays 1133, the semiconductor wafers are delivered to a different bay 1133 so that another process may be performed.

In such a conventional semiconductor fabrication system, a single clean room 1113 occupies a large area. For example, since each bay 1133 has a long side, an operator may have to carry a cassette containing the semiconductor wafers across the length of the bay 1113 to place the cassette into the semiconductor wafer delivery system 1300. As a result, the time between processes may increase and productivity may decrease.

### SUMMARY OF THE INVENTION

At least one exemplary embodiment of the present invention provides a system for fabricating semiconductor devices that has a clean room on two floors. The fabrication system may include first and second clean rooms on upper and lower floors respectively. Each of the first and second clean rooms may include a plurality of main bays that contain semiconductor fabrication apparatuses for performing semiconductor processes. The main bays may be positioned adjacent to each other and along a long side of the clean room. The paths may include a main path positioned substantially perpendicular to the main bays to divide the main bays into a plurality of sub bays. The paths may also include at least one sub path positioned substantially parallel to the main paths. In particular, the paths may include a main path substantially perpendicularly crossing the main bays at a central location in the clean room and sub paths positioned substantially parallel to each other and the main path and positioned on opposite sides of the main path. Such a configuration permits a smooth flow of operators and articles within the clean rooms, which increases productivity.

The sub bays may include a plurality of semiconductor fabrication apparatuses for performing fabrication processes. The semiconductor fabrication apparatuses may be arranged in a line along a long side of the sub bay or they may be arranged in two substantially parallel lines along the walls of the sub bay. The sub bay may also include a bay path in its lengthwise direction.

Semiconductor wafer delivery systems may be located in each of the sub bays for transferring semiconductor wafers between the first and second clean rooms. The semiconductor wafer delivery systems may be positioned adjacent to entrances within the sub bays and adjacent to the sub paths. The semiconductor wafer delivery system may include a delivery member that connects the first and second clean room. Each semiconductor wafer delivery system may also include a first inlet/outlet portion attached to the delivery member in the first clean room and a second inlet/outlet portion attached to the delivery member in the second clean room. Cassettes containing semiconductor wafers may be input into and output from the delivery member via the inlet/outlet portions. The semiconductor wafer delivery system may also include a cassette moving unit which moves through the delivery member to transfer the cassette between the first inlet/outlet portion and the second inlet/outlet portion. A cassette storage portion for storing a plurality of cassettes may also be included in the semiconductor delivery system. Cassettes may be discharged out of the cassette storage portion to maintain a flow of cassettes through the delivery member.

The semiconductor wafer delivery system may be substantially vertically formed to connect a sub bay of the first clean room containing semiconductor fabrication apparatuses and a sub bay of the second clean room containing semiconductor fabrication apparatuses so that fabrication processes (e.g., consecutive fabrication processes) for a semiconductor wafer may be consecutively performed by performing the first fabrication process, transferring the semiconductor to the second sub bay, and performing the second fabrication process. By transferring the semiconductor wafers between the first clean room and the second clean room in a substantially vertical manner, the distance that the semiconductor wafer must travel between semiconductor fabrication processes may be reduced and productivity may be increased.

At least one exemplary embodiment of the present invention provides a method of transferring a semiconductor wafer between a first clean room and a second clean room. The first fabrication process may be conducted in a sub bay in the first clean room that contains semiconductor fabrication apparatuses for the first fabrication process. Once the fabrication process is performed on the semiconductor wafer in the first clean room, the wafer may be transferred through the delivery member of a semiconductor wafer delivery apparatus (e.g., via a cassette) to a sub bay in the second clean room that contains semiconductor fabrication apparatuses for the subsequent fabrication process. The subsequent fabrication process may then be performed. The subsequent fabrication processes may include a photolithographic process and an ion implanting process or a photolithographic process and a dry etching process.

### BRIEF DESCRIPTION OF THE DRAWINGS

Exemplary embodiments of the present invention will be readily understood with reference to the following detailed description thereof provided in conjunction with the accompanying drawings in which:

FIG. 1 is a perspective view of a conventional fabrication system having a clean room for producing semiconductor devices.

FIG. 2 is a schematic plan view of a clean room of a conventional fabrication system for producing semiconductor devices.

FIG. 3 is a perspective view of a fabrication system having a clean room on two floors for producing semiconductor devices according to an exemplary embodiment of the present invention.

FIG. 4 is a schematic plan view of a clean room of the fabrication system according to the exemplary embodiment shown in FIG. 3.

FIG. 5 is a cross-sectional view showing a semiconductor wafer delivery system that may be installed in the fabrication system according to the exemplary embodiment shown in FIG. 3.

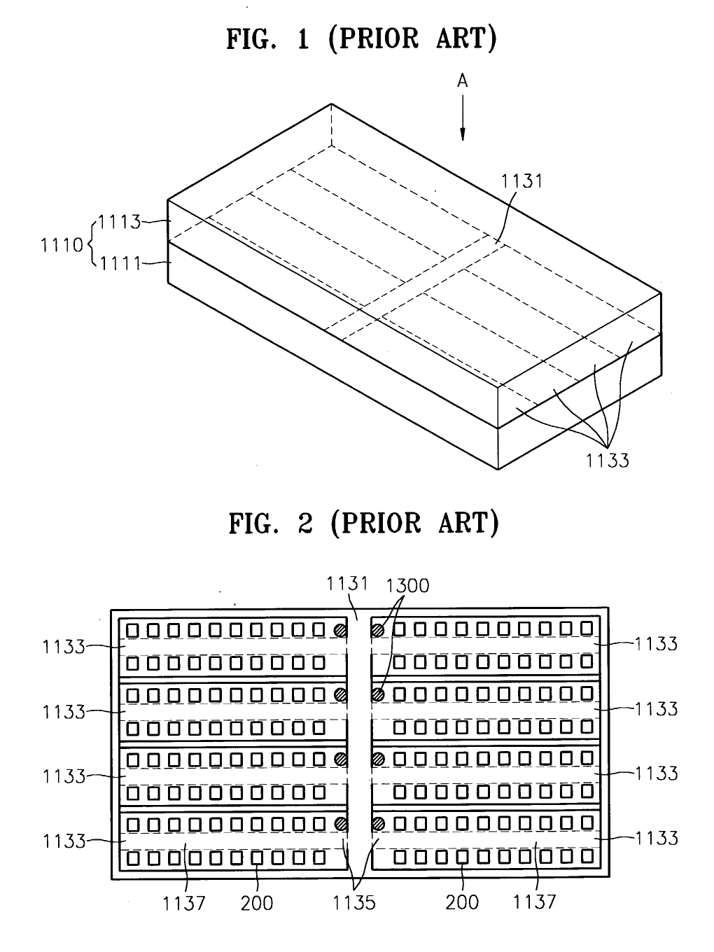

### DETAILED DESCRIPTION OF EXEMPLARY EMBODIMENTS OF THE INVENTION

Hereinafter, exemplary embodiments of the present invention will be described in detail with reference to the attached drawings, in which exemplary embodiments of the invention are shown. The invention may, however, be embodied in many different forms and should not be construed as being limited to the exemplary embodiments set forth herein. Rather, these exemplary embodiments are provided so that this disclosure will be thorough and complete and will fully convey the concept of the present invention to those skilled in the art. It is to be understood that when an element is referred to as being “between” two other elements, it may be positioned such that the two other elements contact the element, or intervening elements may be present. It is to be further understood that when an element is referred to as being “adjacent” to another element, it may be positioned such that it contacts the element, or intervening elements may be present. In addition, it is to be understood that when an element is referred to as being “substantially parallel” to an element, it can be parallel or close to parallel to the element. Furthermore, it is to be understood that when an element is referred to as being “substantially vertical” to an element, it can be vertical or close to vertical to the element. Additionally, it is to be understood that when an element is referred to as being “substantially perpendicular”, it can be perpendicular or close to perpendicular to the element. Throughout the specification, like numbers refer to like elements.

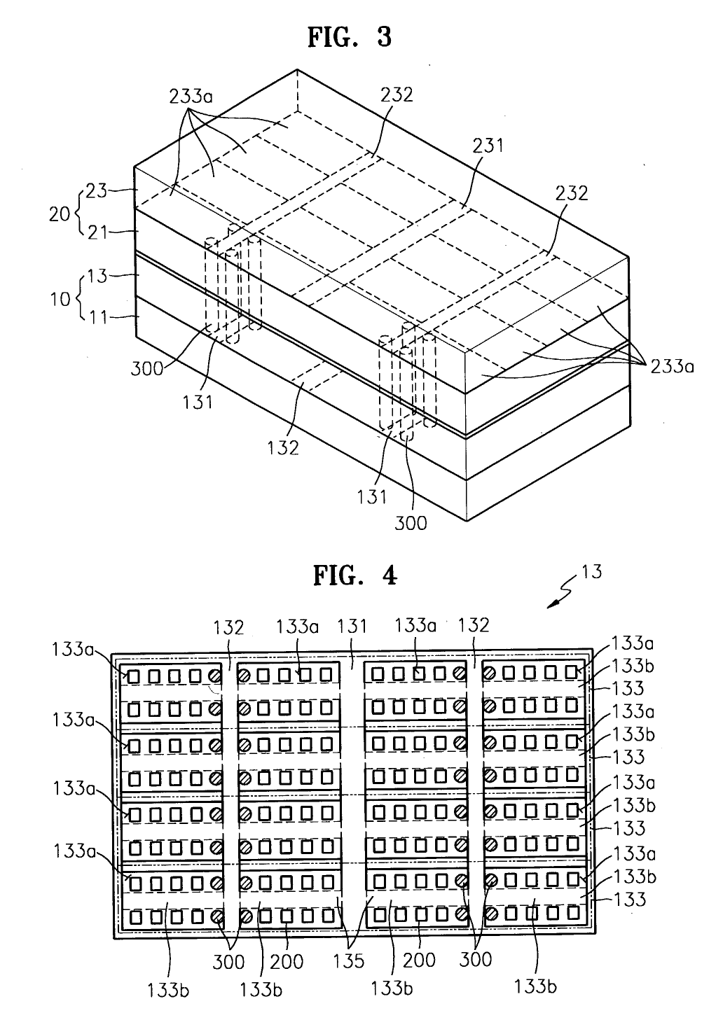

FIG. 3 is a schematic perspective view of a fabrication system for producing semiconductor devices that has a clean room on two floors according to an exemplary embodiment of the present invention. FIG. 4 is a plan view of a first clean room of the fabrication system illustrated in FIG. 3.

Referring to FIG. 3, the fabrication system includes a first floor 10 that includes a first clean room 13 and a first service floor 11 located below the first clean room 13 and a second floor 20 that includes a second clean room 23 and a second service floor 21 located below the first clean room 23.

Referring to FIG. 4, the first clean room 13 may have a rectangular shape. Although a rectangular shape is depicted in FIG. 4, other geometrical shapes for the clean room 13 are within the purview of one of skill in the art. A plurality of main bays 133 are located adjacent to each other and are positioned along a long side of the clean room 13. A main path 131 may be located along a central line substantially perpendicular to the lengthwise direction of the main bays 133. The main path 131 may be a path wide enough to move general articles or new apparatuses therethrough. Sub paths 132 are positioned substantially parallel to the main path 131 and are substantially perpendicular to the lengthwise direction of the main bays 133. The sub paths divide the main bays 133 into sub bays 133a. The sub path 132 may be more narrow than the main path 131, but may be wide enough to permit a repairman to carry tools for repairing semiconductor fabrication apparatuses 200. In the first clean room 13 depicted in FIG. 4, each main bay 133 is divided into two sections by the main path 131, and each section of the main bay 133 is divided into two sub bays 133a by each sub path 132.

Although FIG. 4 depicts the main path 131 as being centrally located and the sub paths 132 being positioned on either side of the main path 131, other exemplary embodiments are envisioned. For example, the main path 131 may be located at one side (e.g., against the wall) of the clean room 13 and substantially perpendicular to the lengthwise direction of the main bays 133. One or more sub paths 132 may be located to one side of the main path 131. Alternatively, the clean room 13 may include a plurality of main paths 131 that are positioned substantially perpendicular to the lengthwise direction of the main bays 133 and a plurality of sub paths 132 that are substantially parallel to the main paths 131. Each of these sub paths 132 may be positioned between two main paths 131, e.g., none of the sub paths 132 are positioned next to each other and none of the main paths 131 are positioned next to each other. In yet another alternative exemplary embodiment, the clean room 13 may include a plurality of main paths 131 and no sub paths 132. For example, the clean room 13 may include two main paths 131 substantially perpendicularly crossing the main bays 133 at opposite sides of the main bays 133.

Semiconductor wafer delivery systems 300 may be installed adjacent to entrances 135 within the sub bays 133a such that semiconductor wafers may be moved between the first clean room 13 and the second clean room 23. For example, the semiconductor wafer delivery systems 300 may be located near the entrance 135 of each sub bay 133a and along the sub paths 132 to move semiconductor wafers from a sub bay 133a of the first clean room 13 on the first floor 10 to a sub bay of the second clean room 23 on the second floor 20 (e.g., sub bay 233a shown in FIG. 3). Although the semiconductor wafer delivery systems are depicted as being located along the sub paths 132, they may be positioned at other locations in the sub bays 133a. For example, they may be positioned along the main path 131.

Each sub bay 133a may have a bay path 133b formed internally along its lengthwise direction. The bay path 133b may have a size sufficient to permit an operator to walk or move articles through the bay path 133b. In the exemplary embodiment depicted in FIG. 4, a sub bay 133a that is adjacent to the major path 131 has two entrances 135 at opposite sides of the sub bay 133a. On the other hand, a sub bay 133a that contacts a wall of the first clean room 13 at one side has one entrance 135 located at the side of the sub bay 133a that is positioned opposite the wall. Semiconductor fabrication apparatuses 200 that perform similar processes may be located in each sub bay 133a. The semiconductor fabrication apparatuses 200 may be arranged in a single line along one side of the sub bay 133a or may be arranged in substantially parallel lines along the bay path 133b.

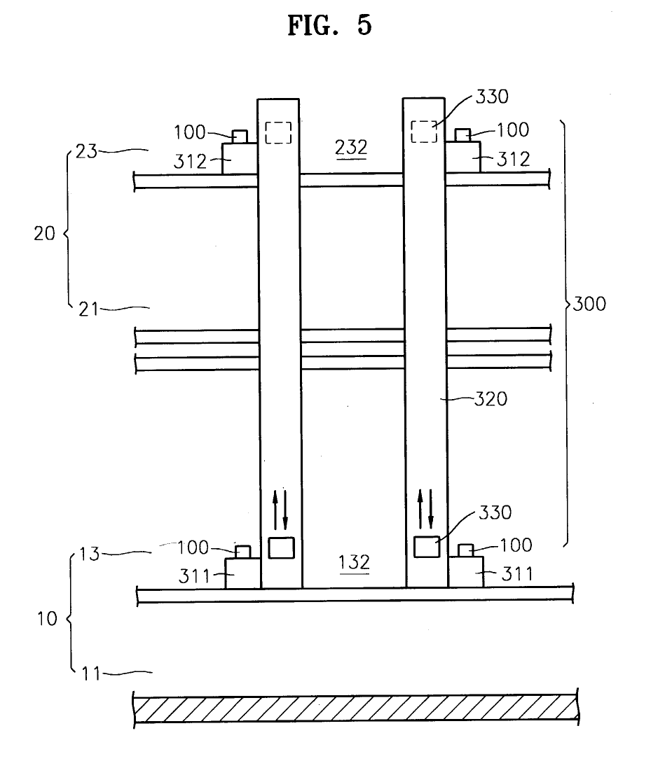

FIG. 5 is a cross-sectional view showing a semiconductor wafer delivery system 300 that may be used in the fabrication system illustrated in FIG. 3 to transfer semiconductor wafers from the first clean room to the second clean room. The semiconductor wafer delivery system 300 may include a first inlet/outlet portion 311 and a second inlet/outlet portion 312. In one exemplary embodiment, cassettes 100 that contain semiconductor wafers may be input into or output from the semiconductor wafer delivery system 300 through the inlet/outlet portions 311 and 312. In particular, a cassette may be input into the first inlet/outlet portion 311 at a sub bay 133a in the first clean room 13 and output from the second inlet/outlet portion in a sub bay 233a in the second clean room 23. The semiconductor wafer delivery system 300 may also include a delivery member 320 that extends through a dividing member that separates the first clean room 13 and the second clean room 23 and which connects the first inlet/output portion 311 and the second inlet/outlet portion 312. The delivery member 320 may have a substantially vertical orientation. A substantially vertical orientation of the delivery member 320 provides a short distance between a sub bay 133a of the first clean room 13 on the first floor 10 and a sub bay 233a of the second clean room 23 on the second floor 20.

In addition, the semiconductor wafer delivery system 300 may include a cassette moving unit 330 which moves through the delivery member 320 to transfer the cassette 100 between the first inlet/outlet portion 311 located in the first clean room 13 and the second inlet/outlet portion 312 located in the second clean room. The semiconductor wafer delivery system 300 may also include a cassette storage portion (not shown) that includes a plurality of cassette storages (not shown). Cassettes 100 may be discharged out of the cassette storage portion to maintain a flow of cassettes 100 being transferred between the first inlet/outlet portion 311 and the second inlet/outlet portion 312, e.g., the cassettes 100 may be moved to a sub bay 133a of the first clean room 13 or a sub bay 233a of the second clean room 23 through the delivery member 320. In addition, the cassette storage portion may discharge the cassettes 100 in the order in which they were input into the cassette storage portion.

As described above, subsequent fabrication processes may be conducted on a semiconductor wafer when one process is conducted in a sub bay 133a in the first clean room 13 and the subsequent fabrication process is conducted in a sub bay of the second clean room 23. In particular, the first fabrication process may be conducted in a sub bay 133a in the first clean room 13 that contains the appropriate semiconductor fabrication apparatuses 200 for the first fabrication process. Once the first fabrication process is complete, a cassette 100 containing the processed semiconductor wafer may be input into the first inlet/outlet portion 311. The cassette is transferred through the delivery member 320 to the second inlet/outlet portion 312 positioned in the sub bay in the second clean room 23 that contains semiconductor fabrication apparatuses 200 for the subsequent fabrication process. The subsequent fabrication process may then be performed.

For example, when the consecutive fabrication processes are a photolithographic process and an ion implanting process, semiconductor fabrication apparatuses 200 for performing the photolithographic process may be located in a sub bay 133a of the first clean room 13, and semiconductor fabrication apparatuses 200 for performing the ion implanting process may be located in a sub bay of the second clean room 23. The sub bay of the second clean room that contains the semiconductor fabrication apparatuses 200 for performing the ion implanting process may be positioned above the sub bay 133a of the first clean room 13 that contains the semiconductor fabrication apparatuses 200 for performing the photolithographic process. After the photolithographic process has been performed on a semiconductor wafer in the sub bay 133a of the first clean room 13, the semiconductor wafer may be moved (e.g., substantially vertically) to a sub bay 233a of the second clean room 23 using the semiconductor wafer delivery system 300. Once the wafer is transferred to a sub bay 233a of the second clean room 23 that contains the semiconductor fabrication apparatuses 200 for performing the ion implanting process, the ion implanting process may be performed. Alternatively, the first fabrication process may be a photolithographic process and the second fabrication process may be a dry etching process. Although two consecutive processes are described herein, it is contemplated that further processes may be conducted if appropriate semiconductor fabrication apparatuses are provided in the sub bays 133a and 233a of the first and second clean rooms 13 and 23 respectively.

Fabrication systems according to exemplary embodiments of the present invention which have a clean room on two floors may reduce the distance an operator has to travel to perform subsequent processes on a semiconductor wafer. By reducing the traveling distance, productivity may be increased and fabrication time may be reduced. In addition, by substantially vertically transferring the semiconductor wafers between the first clean room 13 and the second clean room 23, the distance that the semiconductor wafer must travel between processes may be reduced. As a result, productivity may be increased. Further, because the area of a clean room accommodating semiconductor fabrication apparatuses may be doubled in a fabrication system that has a clean room on two floors according to exemplary embodiments of the present invention, semiconductor fabrication apparatuses may be positioned in different locations and managed in numerous ways to increase productivity.

Although exemplary embodiments of this invention have been described in detail hereinabove, it should be understood by those of ordinary skill in the art that various changes in form and details may be made therein and will still fall within the spirit and scope of the present invention as defined in the appended claims.

What is claimed is:

1. A fabrication system for producing semiconductor devices having first and second clean rooms on upper and lower floors, each of the first and second clean rooms comprising:
a plurality of main bays positioned adjacent to each other; and
a plurality of semiconductor wafer delivery systems located in sub bays to move semiconductor wafers between the first and second clean rooms.

2. The fabrication system of claim 1, wherein the main bays include a plurality of semiconductor fabrication apparatuses for performing semiconductor processes.

3. The fabrication system of claim 2, wherein the main bay has at least one long side and at least one short side and the semiconductor fabrication apparatuses are disposed along at least one of the long sides of the main bay.

4. The fabrication system of claim 1, wherein the semiconductor wafer delivery systems are located adjacent to paths positioned substantially perpendicular to the main bays.

5. The fabrication system of claim 4, wherein the semiconductor wafer delivery systems substantially vertically connect the first and second clean rooms.

6. The fabrication system of claim 4, wherein the paths comprise:
a main path substantially perpendicularly crossing each of the main bays at their centers; and
sub paths substantially parallel to each other and positioned at opposite sides of the main path.

7. The fabrication system of claim 6, wherein the main path divides the main bay into a first portion and a second portion, the first portion and the second portion being substantially equal in size, and wherein the sub paths substantially perpendicularly cross the main bays substantially at the centers of the first portion and the second portion.

8. The fabrication system of claim 4, wherein the paths include a plurality of main paths substantially perpendicularly crossing the main bays.

9. The fabrication system of claim 4, wherein the paths include two main paths substantially perpendicularly crossing the main bays at opposite outer sides of the main bays.

10. The fabrication system of claim 4, wherein the paths include:
a main path substantially perpendicularly crossing each of the main bays at an outer side of the main bays; and
at least one sub path substantially parallel to the main path at one side of the main path.

11. The fabrication system of claim 4, wherein the paths include:
at least one main path substantially perpendicularly crossing each of the main bays; and
at least one sub path substantially parallel to the main paths.

12. The fabrication system of claim 4, wherein the paths include:
a plurality of main paths substantially perpendicularly crossing each of the main bays; and
a plurality of sub paths substantially parallel to the main paths;
wherein each of the sub paths are positioned between two main paths.

13. The fabrication system of claim 4, wherein each sub bay includes a bay path formed substantially perpendicular to the paths.

14. The fabrication system of claim 13, wherein each sub bay includes a plurality of semiconductor fabrication apparatuses arranged along the bay path on at least one side of the sub bay.

15. The fabrication system of claim 14, wherein the semiconductor fabrication apparatuses are arranged in lines along each side of the bay path.

16. The fabrication system of claim 1, wherein each semiconductor wafer delivery system includes:
a delivery member connecting the first clean room to the second clean room; and
first and second inlet/outlet portions connected to the delivery member for inserting and removing semiconductor wafers from the delivery member.

17. The fabrication system of claim 16, wherein each of the first and second inlet/outlet portions includes a cassette storage portion for storing a plurality of cassettes.

18. The fabrication system of claim 1, wherein at least one of the semiconductor wafer delivery systems substantially vertically connects a first sub bay of the first clean room and a second sub bay of the second clean room; and
wherein at least one semiconductor fabrication apparatus for performing a first semiconductor fabrication process is located in the first sub bay and at least one semiconductor fabrication apparatus for performing a second, consecutive semiconductor fabrication process is located in the second sub bay.

19. The fabrication system of claim 18, wherein the first semiconductor fabrication process is a photolithographic process and the second semiconductor fabrication process is an ion implanting process.

20. The fabrication system of claim 18, wherein the first semiconductor fabrication process is a photolithographic process and the second semiconductor fabrication process is a dry etching process.

21. A clean room for producing semiconductor devices comprising:
a plurality of sub bays formed into rows, the rows of sub bays being separated from each other by a plurality of paths; and
a plurality of semiconductor wafer delivery systems in each sub bay.

22. The clean room according to claim 21, wherein the paths include:
a main path centrally located in the clean room substantially parallel to the rows of sub bays; and
sub paths substantially parallel to the main path and positioned at opposite sides of the main path.

23. The clean room according to claim 21, wherein the paths include:
a plurality of main paths substantially parallel to the rows of sub bays.

24. The clean room according to claim 23, wherein the paths include:
two main paths substantially parallel to the rows of sub bays positioned at opposite sides of the clean room.

25. The clean room according to claim 24, wherein the paths further include at least one sub path substantially parallel to the rows of sub bays and positioned between the two main paths.

26. The clean room according to claim 21, wherein the paths include:
a main path substantially parallel to the rows of sub bays at one side of the clean room; and
at least one sub path substantially parallel to the rows of sub bays and positioned at one side of the main path.

27. The clean room according to claim 21, wherein the paths include:
a plurality of main paths, substantially parallel to the rows of sub bays; and
at least one sub path, substantially parallel to the rows of sub bays;
wherein each of the sub paths are positioned between two main paths.

28. The clean room according to claim 21, wherein the sub bays include a plurality of semiconductor fabrication apparatuses for performing semiconductor processes.

29. The clean room according to claim 21, wherein the semiconductor wafer delivery systems are positioned adjacent to the paths.

30. The clean room according to claim 21, wherein each sub bay includes a bay path positioned substantially perpendicular to the rows of sub bays.

31. The clean room according to claim 30, wherein each sub bay includes a plurality of semiconductor fabrication apparatuses arranged along at least one side of the bay path.

32. The clean room according to claim 30, wherein the semiconductor wafer delivery systems are located adjacent to an entrance of the sub bay along the bay path.

33. A semiconductor wafer delivery system comprising:
a delivery member interconnecting a first clean room and a second clean room;
a first inlet/outlet portion connected to the delivery member in the first clean room; and
a second inlet/outlet portion connected to the delivery member in the second clean room.

34. The semiconductor wafer delivery system of claim 33, further comprising:
a cassette moving unit positioned internally in the delivery member for transferring a cassette containing semiconductor wafers between the first and second clean rooms.

35. The semiconductor wafer delivery system of claim 34, further comprising a cassette storage portion for storing a plurality of cassettes.

36. The semiconductor wafer delivery system of claim 33, wherein the delivery member is positioned substantially vertically between the first clean room and the second clean room.

37. A method of transferring a semiconductor wafer between a first clean room and a second clean room comprising:
placing at least one semiconductor wafer into a delivery member interconnecting the first clean room and the second clean room; and
transferring the semiconductor wafer through the delivery member utilizing the semiconductor wafer delivery system of claim 33.

38. A method of performing subsequent fabrication processes on a semiconductor wafer comprising:
performing a first fabrication process on a semiconductor wafer in a first sub bay located in a first clean room;
transferring the semiconductor wafer to a second clean room; and
performing a second fabrication process on the semiconductor wafer in a second sub bay located in a second clean room.

39. The method of claim 38, further comprising placing the semiconductor wafer into a cassette and inserting it into a delivery member interconnecting the first and second clean rooms.

40. The method of claim 39, further comprising placing the cassette into an first input/output portion attached to the delivery member in the first clean room prior to transferring the semiconductor wafer to the second clean room.

41. The method of claim 40, further comprising removing the cassette from the delivery member through a second input/output portion attached to the delivery member in the second clean room after transferring the semiconductor wafer to the second clean room.

42. A method of performing subsequent fabrication processes on a semiconductor wafer comprising:
performing a first fabrication process on a semiconductor wafer in a first sub bay located in a first clean room;
transferring the semiconductor wafer to a second clean room; and
performing a second fabrication process on the semiconductor wafer in a second sub bay located in a second clean room utilizing the fabrication system of claim 1.
